(19) United States
(12) Patent Application Publication
(10) Pub. No.: US 2021/0011061 A1
(43) Pub. Date: Jan. 14, 2021

(54) Harmonics Measurement in Power Grids

(71) Applicant: innogy SE, Essen (DE)

(72) Inventor: Jörn Runge, Marklohe (DE)

(21) Appl. No.: 16/981,326

(22) PCT Filed: Feb. 19, 2019
(86) PCT No.: PCT/EP2019/054043

§ 371 Date: Sep. 16, 2020

(30) Foreign Application Priority Data
Mar. 16, 2018 (DE) 10 2018 106 200.1

(51) Int. Cl. G01R 19/25; H02J 3/24; H02J 3/38

(52) U.S. Cl. CPC G01R 19/2513; H02J 3/381; H02J 3/24

(57) ABSTRACT

The subject-matter relates to a method, performed by at least one apparatus, including: determining of a correction factor for at least one first voltage transformer arranged in a power grid, the correction factor being indicative of a correction for obtaining correct measured values measured by the at least one first voltage transformer, wherein the determining of the correction factor of the at least one first voltage transformer being performed at least partially based on a first measured voltage of the at least one first voltage transformer and a second measured voltage of the at least one first voltage transformer, wherein the second voltage of the at least one first voltage transformer is determined at least partially based on a known transfer function of at least one second voltage transformer and the first voltage of the at least one first voltage transformer is determined without taking into account the known transfer function of the at least one second voltage transformer; determining a calibration factor for the at least one first voltage transformer based at least in part on the determined correction factor; and outputting or causing the output of the determined calibration factor. The subject matter further relates to a correspondingly configured apparatus and a system.

### CROSS-REFERENCE TO RELATED APPLICATIONS

This application is the United States national phase of International Application No. PCT/EP2019/054043 filed Feb. 19, 2019, and claims priority to German Patent Application No. 10 2018 106 200.1 filed Mar. 16, 2018, the disclosures of which are hereby incorporated by reference in their entirety.

### BACKGROUND OF THE INVENTION

### Field of the Invention

The present subject-matter relates to a method, an apparatus and a system for optimised measurement of harmonics in power grids, in particular offshore and/or onshore grids, which are subject to harmonic loading, e.g. by a feed-in of electrical energy from wind turbine generators (WTG).

### Description of Related Art

Inductive voltage transformers are very inexpensive and therefore widely used. However, they are usually unable to measure voltages with frequencies higher than 50 Hz accurately, as the transfer function of inductive voltage transformers is not known. Measuring inductive voltage transformers, especially those already installed, is very costly and therefore unusual.

In onshore and/or offshore grids with high-voltage direct current transmission (HVDC) connections, the harmonic load is/will be increased by additional power generation facilities (e.g. WTG). The reasons for this are the increased use of converters and the trend towards less voltage-stiff networks. A correct measurement of the harmonic load in such power grids is necessary to find the cause (technical and/or legal).

Voltage transformers that measure correctly over the frequency range of interest from 50 Hz to 10 kHz are considerably more expensive than conventional inductive voltage transformers.

In addition, the standard measuring instruments used up to now are regularly calibrated only to a fundamental oscillation—also known as the nominal frequency—of the power grid of 50 Hz. At frequencies not equal to 50 Hz (e.g. in WTGs), especially above 1000 Hz, an accurate harmonic measurement cannot be guaranteed. The example of a frequency above 1000 Hz may be present in the power grid in some cases, e.g. due to resonances, individual components of the power grid may be loaded with such high frequencies.

From US 2002/171433 A1 a voltage measuring device is known to improve the measuring accuracy of an electrical power meter. The voltage measuring device is for a sheathed power cable, and includes a first conductive element arranged to contact the sheathing material for sheathing a power cable conductor, a second conductive element for forming a capacitance between the ground and itself; current-voltage converting means for converting into the voltage signal having a waveform proportional to the current signal flowing between the first conductive member and the second conductive member; and voltage value calculating means for calculating the voltage value applied to the power cable from the voltage signal converted by the current-voltage converting means.

### SUMMARY OF THE INVENTION

Based on this background, it is desirable to provide a solution that avoids or minimizes the disadvantages described above and, in particular, allows for a cost-effective and accurate measurement of harmonics in power grids even at frequencies higher than 50 Hz.

The technical object of the present subject-matter is therefore to provide a solution that enables a cost-effective and accurate measurement of harmonics in the power grid.

According to a first exemplary aspect of the invention, a method is disclosed which comprises the following:
determining of a correction factor for at least one first voltage transformer arranged in a power grid, the correction factor being indicative of a correction for obtaining correct measured values measured by the at least one first voltage transformer, wherein the determining of the correction factor of the at least one first voltage transformer being performed at least partially based on a first measured voltage of the at least one first voltage transformer and a second measured voltage of the at least one first voltage transformer, wherein the second measured voltage of the at least one first voltage transformer is determined at least partially based on a known transfer function of at least one second voltage transformer and the first measured voltage of the at least one first voltage transformer is determined without taking into account the known transfer function of the at least one second voltage transformer;
thereby the second measurement of the first transformer is multiplied by the quotient from the frequency-dependent measurements of the second transformer divided by the previously recorded frequency-dependent first measurements of the first transformer, this quotient being referred to as the transfer function, and the correction factor for a frequency range from 50 Hz to 10 kHz being determined by means of the at least one second voltage transformer;
determining a calibration factor for the at least one first voltage transformer based at least in part on the determined correction factor; and
outputting or causing the output of the determined calibration factor.

According to a second exemplary aspect of the invention, an apparatus is disclosed which is arranged to execute and/or control the method according to the first aspect of the invention or comprises respective means for executing and/or controlling the steps of the method according to the first aspect of the invention. Either all steps of the method can be controlled, or all steps of the method can be executed, or one or more steps can be controlled and one or more steps can be executed. One or more of the means may also be executed and/or controlled by the same unit. For example, one or more of the means can be performed by one or more processors.

According to a third exemplary aspect of the invention, an apparatus comprising at least one processor and at least one memory comprising program code is disclosed, the memory and the program code being arranged to cause an apparatus (for example the apparatus comprising the processor and the memory) to execute and/or control at least the method according to the first aspect of the invention. In doing so, either all steps of the method can be controlled, or all steps of the method can be executed, or one or more steps can be controlled and one or more steps can be executed.

According to a fourth exemplary aspect of the invention, a system is disclosed comprising one or more apparatuses adapted to execute and/or control the method according to the first aspect of the invention or having means for executing and/or controlling the steps of the method according to the first aspect of the invention. Either all steps of the method can be controlled, or all steps of the method can be executed, or one or more steps can be controlled and one or more steps can be executed.

According to a fifth exemplary aspect of the invention, a computer program is disclosed which comprises program instructions which cause a processor to execute and/or control the method according to the first aspect of the invention when the computer program is executed by the processor. In this specification, a processor is to be understood as, inter alia, control units, microprocessors, microcontrol units such as microcontrollers, digital signal processors (DSP), application specific integrated circuits (SASICs) or field programmable gate arrays (FPGAs). Either all steps of the method can be controlled, or all steps of the method can be executed, or one or more steps can be controlled and one or more steps executed. For example, the computer program can be distributed over a network such as the Internet, a telephone or mobile network, and/or a local area network. The computer program may be at least in part software and/or firmware of a processor. It may also be at least partially implemented as hardware. For example, the computer program may be stored on a computer-readable storage medium, such as a magnetic, electrical, electromagnetic, optical and/or other storage medium. The storage medium may, for example, be part of the processor, for example, a (non-volatile or volatile) program memory of the processor or a part thereof. For example, the storage medium may be tangible and/or non-transitory.

These five aspects of the present invention have, among other things, the features described below, some of which are exemplary.

The term harmonics is used in the sense of the present subject-matter to refer to occurring or resulting harmonics and/or interharmonics in the power grid.

The subject-matter of the invention is based on the finding that an e.g. temporary replacement of an inductive voltage transformer (e.g. at all three phases of a voltage measuring point existing in the power grid) by a voltage transformer—in this case the at least one second voltage transformer—with a known transfer function (e.g. a capacitive voltage transformer or an already measured inductive voltage transformer) makes it possible to determine a calibration factor with this at least one second voltage transformer, a correct transfer function for the at least one first voltage transformer being determinable at least partially based on this calibration factor. Furthermore, it is possible to determine a calibration factor for all further voltage transformers and inductive voltage transformer arranged in electrical proximity (e.g. connected on the same busbar or by means of a cable of short length). With the measured at least one second voltage transformer it is possible, for example, to determine the transfer function of the at least one first voltage transformer not yet measured (or all electrically close voltage transformers not yet measured). Subsequently, the at least one second voltage transformer can be exchanged with the (e.g. not yet measured) voltage transformer previously comprised by the power grid. After determining the transfer function of the first voltage transformer included in the power grid, as well as further inductive voltage transformers (e.g. further first voltage transformers) arranged in electrical proximity to the at least one second voltage transformer during the arrangement of the latter, an exact (i.e. in particular) correct harmonic measurement is then possible, even at frequencies higher than or frequencies not equal to 50 Hz, for example with the first voltage transformers already used in the power grid. The harmonic measurement can be a frequency-dependent voltage measurement, for example. Accordingly, the components already present in the power grid, in particular the inductive voltage transformers, can be continued to be used.

The transfer function of a (e.g. first) voltage transformer is, for example, indicative of the transmission behaviour of the voltage transformer in the power grid. For example, the transfer function comprises the amplitude and phase spectrum, which can be determined accordingly. From these spectra, the transfer behavior represented by the determined transfer function can then be determined (e.g. derived and/or calculated). The amplitude and phase spectrum can, for example, be determined at least partially based on a frequency-dependent voltage measurement performed by the at least one first voltage transformer.

For example, the transfer function also represents a quotient of the spectra of an input and response signal. The transfer function can be determined (e.g. calculated) based on the input and response signal. There are certain dependencies between the amplitude and phase response of the at least one first voltage transformer, which allow conclusions to be drawn about the transfer function of the at least one first voltage transformer. For example, for a given amplitude response, there is only a finite number of possibilities for the phase response (e.g. with finite pole and zero positions). This also applies vice versa, for example: Except for a scaling factor, the phase response is clearly defined by the amplitude response.

The determining of the correction factor for at least one first voltage transformer arranged in a power grid can be carried out and/or performed, for example, by measuring the first and second voltage according to the features of the step. The measurement of the first and the second voltage in the sense of the present subject-matter represents in particular a harmonic measurement, the measurement of the first and the second voltage being for example a frequency-dependent voltage measurement.

The measured values measured by the at least one first voltage transformer are, for example, voltage, current, amplitude, phase, or a combination thereof, wherein the measured values are determined in each case as a function of frequency.

For example, the calibration factor represents a factor that can be calculated (e.g. multiplied) with the measured values measured by the at least one first voltage transformer so that the measured values correspond to the correct ones (i.e. are corrected). The determining of the calibration factor can be carried out and/or controlled in particular when harmonics occur, since in this case deviations between the first voltage (e.g. measurement by the at least one first voltage transformer) and the second voltage (e.g. measurement by the at least one second voltage transformer, which is e.g. a capacitive or a measured inductive voltage transformer) may be present. Based on the calibration factor, for correct harmonic measurement by the at least one first voltage transformer, in particular the measurement by the at least one first voltage transformer of the current network cannot be changed to determine the exact measured values, but the measured values determined by the at least one first voltage transformer are corrected subsequently by means of the calibration factor. In order to be able to determine this calibration factor correctly, it is provided that, for example, the at least one second voltage transformer is arranged in the power grid at least temporarily, so that in particular deviations between the measured values determined by the at least one first voltage transformer and those which are actually present can be determined.

Subsequently, the determined calibration factor is output or its output is initiated/caused, e.g. to another entity that can process the calibration factor, such as a monitoring system (e.g. network control system, to name just one non-limiting example) that monitors the power grid and is used by a network control center of the power grid. This monitoring system can, for example, use the determined calibration factor to determine the actual measured values of at least one first voltage transformer. In this way, for example, occurring harmonics can be quickly detected so that suitable measures can be taken, for example. Optionally, the determined correction factor can also be output or its output can be initiated.

In particular, the power grid is one or at least part of an offshore and/or onshore power grid, with WTGs in particular feeding electrical energy into the power grid or the at least part of the offshore and/or onshore power grid. The power grid is, for example, a three-phase power grid.

For example, the power grid may be part of an offshore substation and/or onshore substation for wind farms, or be comprised in an offshore substation and/or onshore substation for wind farms. For example, the power grid may be part of a substation for photovoltaic installations or be comprised in a substation for photovoltaic installations. Such substations are needed, for example, to convert electrical energy generated by an offshore and/or onshore wind farm and/or photovoltaic installation so that the electrical energy generated is transmitted for transmission through the power grid operatively connected to the offshore and/or onshore wind farm and/or photovoltaic installation. In particular, offshore substations and/or onshore substations for wind farms and/or substations for photovoltaic systems represent possible concrete implementations or areas of application for the present subject-matter.

A voltage transformer is understood to be, in particular, a voltage transformer in the field of electrical power engineering that is designed to measure the alternating voltage of a power grid. The mode of operation of such a voltage transformer consists in particular in proportionally transferring the high voltage to be measured to low voltage values. These low voltage values can be transmitted to voltage measuring devices, energy meters, systems monitoring the power grid (e.g. monitoring systems of a network control system), or similar, for which purpose voltage transformers are provided for such measuring purposes.

The at least one first voltage transformer is in particular an inductive voltage transformer. An inductive voltage transformer is understood to be an inductive voltage transformer that is basically designed like a transformer. Such inductive voltage transformers comprise a primary winding that is electrically connected to the voltage to be measured and a secondary winding that is electrically isolated. To determine measured values, such inductive voltage transformers have means of maintaining small deviations in the transformation ratio and small misalignment angles in the phase shift between primary and secondary voltage.

Inductive voltage transformers can be arranged on the primary side for the determining of measured values either between two voltage-carrying conductors (outer conductors) or between a conductor and earth. For example, for voltage measurement on a single outer conductor to earth, one end of the primary winding is earthed. For this purpose, the inductive voltage transformer can only have one high voltage connection. There are single-phase versions and three-phase versions for the three-phase alternating current network, wherein three-phase inductive voltage transformers are of particular interest as at least one first voltage transformer.

The second voltage transformer, which is used to determine the transfer function of the at least one first voltage transformer, is in particular a capacitive voltage transformer, or an inductive voltage transformer, which is measured in such a way that it can determine already corrected (i.e. correct) measured values.

According to an exemplary embodiment of all aspects of the invention, the procedure further comprises
determining a corrected transfer function for the at least one first voltage transformer, wherein the corrected transfer function is determined at least in part based on the determined calibration factor; and
outputting or causing the output of the corrected transfer function.

In particular, the corrected transfer function enables a frequency-dependent calibration of the at least one first voltage transformer with a transfer function unknown until then, e.g. according to the following formula:

U2, new(f)=U2, measured(f)*(U1(f)/U2, old(f)),

where
U2, old(f) represents the voltage previously indicated at K2;
U2, new(f) represents the correct voltage to be displayed at K2;
U1(f) represents the correct voltage measured at K1; and
U2, measured(f) represents the voltage currently measured at U2.

U2, new(f) can be used to calibrate the at least one first voltage transformer whose transfer function is unknown. By means of the at least one second voltage transformer (with known transfer function), for example, the correct transfer function of the at least one first voltage transformer (and also of all voltage transformers electrically close to the at least one second voltage transformer (e.g. inductive) voltage transformer, wherein the at least one first voltage transformer, if not exchanged by the at least one second voltage transformer, and/or the voltage transformers electrically close to the at least one second voltage transformer are arranged e.g. on the same busbar as the at least one second voltage transformer, or are arranged behind a short cable lying between the at least one second voltage transformer and voltage transformers electrically close) are determined. For this purpose, for example, a temporary replacement of one (e.g. inductive) voltage transformer (e.g. the at least one first voltage transformer) on all three phases of an existing voltage measuring point by the at least one second (e.g. capacitive or measured inductive) voltage transformer with known transfer function, e.g. at the existing voltage measuring point, can be carried out. Alternatively, the at least one second voltage transformer can be additionally arranged, at least temporarily, e.g. at the busbar at which the at least one first voltage transformer is also arranged. The position (e.g. of the voltage measuring point) where the at least one second voltage transformer is located is marked “K1” above. The correct transfer function of all electrically close (e.g. inductive) voltage transformers can be determined with the at least one second voltage transformer, the position (e.g. voltage measuring point) at which the respective one of the voltage transformers electrically close to the at least one second voltage transformer is arranged being marked by “K2” above. The respective position “K1” or “K2” of the respective voltage transformers are defined, for example, in such a way that “K1” or “K2” represent the respective primary connections of the respective voltage transformers at these positions.

The calibration factor (U1(f)/U2, old (f)) can, for example, be integrated into measuring instruments that use the measured values determined by the at least one first voltage transformer (if, for example, measured data are processed by means of digital signal processing), so that the correct voltage amplitude is then measured at each frequency. This is also possible, for example, in a Supervisory Control and Data Acquisition (SCADA) system (e.g. used by a network control system of the power grid) or in a software by means of which node voltages of the power grid can be displayed (e.g. a Human-Machine-Interface (HMI) software) and/or by means of which they can be evaluated (e.g. by means of a simulation environment). The use of the calibration factor, which is e.g. used by such software, makes it possible that once voltage transformers have been measured, which are used in particular as calibrated measuring instruments in the power grid, they do not have to be re-adjusted, which can be very time-consuming. Based on the measured values of the first voltage transformers comprised by the power grid and the determined calibration factor, correct measured values can always be generated. As a result, harmonics of the power grid in particular can be reliably, accurately and correctly determined (e.g. measured).

According to an exemplary embodiment of all aspects of the invention, the at least one second voltage transformer is temporarily (e.g. for a limited period of time) comprised by the power grid.

The at least one second voltage transformer is, for example, temporarily comprised by the power grid, e.g. by exchanging a voltage transformer already comprised in the power grid with the at least one second voltage transformer. Since the transfer function of the at least one second voltage transformer is known, e.g. in that the at least one second voltage transformer was measured accordingly, e.g. prior to its arrangement in the power grid, the calibration factor of at least one first voltage transformer (which is arranged electrically close to, e.g. on the same busbar as the at least one second voltage transformer) can be determined using the at least one second voltage transformer.

According to an exemplary embodiment of all aspects of the invention, the first voltage and/or the second voltage of the at least one first voltage transformer is determined at (all) three phases of a voltage measuring point existing in the power grid.

The at least one first and the at least one second voltage transformer are arranged, for example, at a voltage measuring point existing in the power grid or comprised by it, so that the at least one first and the at least one second voltage transformer can be used to determine at least the first and second voltage. Furthermore, the current, amplitude(s) and phase(s) or amplitude and phase response of the at least one first voltage transformer can also be determined. For this purpose, the at least one first and the second voltage transformer are comprised by the power grid in such a way that measured values (e.g. voltage, current, amplitude, phase or a combination thereof) can be determined on all three phases of the correspondingly three-phase power grid.

According to an exemplary embodiment of all aspects of the invention, for all (e.g. practically) occurring switching states of the power grid and/or operating states of one or more components of the power grid, the steps of the present method are carried out according to the first aspect of the present invention.

Accordingly, for example, a corresponding determining (e.g. measurement) as described above is carried out in various, in particular all possible switching and/or operating states of the one or more components that the power grid may have or comprises. Such a change of the topology of the power grid by a change of the switching state of the power grid and/or of one or more operating states of the one or more components of the power grid can be carried out, for example, by opening or closing various switches (switching on or off) comprised by the power grid and/or by changing the operating state of one or more components of the power grid (e.g. changing the operating point or speed of a transformer or a generator, to name but a few non-limiting examples). Furthermore, a change in the topology of the power grid can be made, for example by opening or closing connections to nodes of the power grid, e.g. via switches. For example, the topology of the power grid can be changed by opening or closing connections to nodes of the power grid, e.g. via switches. In this way, ring networks—if any—that may be comprised by the power grid, can be modified, to name but one non-limiting example. Since in each possible switching state and/or operating state of the one or more components of the power grid different impairments of the measurement by the at least one first voltage transformer can occur, which are e.g. characterised by a different transmission behaviour of the identical at least one first voltage transformer, it is advantageous to determine an objective correction factor for different, in particular for each of the possible switching states and/or operating states of the one or more components of the power grid.

According to an exemplary embodiment of all aspects of the invention, the at least one second voltage transformer is temporarily arranged in or comprised by the power grid for a measuring period of approximately one day to 6 months.

To determine the calibration factor for the at least one first voltage transformer, the at least one second voltage transformer can be calibrated over a longer period of time (e.g. one day up to several months (e.g. 2, 3, 4, 5 or 6 months), or the like, to name but a few non-limiting examples) and for all (e.g. practically) occurring switching states of the power grid and/or operating states of the one or more components of the power grid, a corresponding determining of the calibration factor (e.g. for each possible switching state of the power grid and/or operating state of the one or more components of the power grid) must be arranged in or comprised by the power grid. Over this longer period of time, for example in the manner described above, the method can be carried out and/or controlled in accordance with the first aspect of the present invention, in particular in order to be able to detect all frequencies occurring with a relevant voltage amplitude. Furthermore, with these correct measurements all further and electrically close inductive voltage transformers can be calibrated for an extended frequency range (e.g. from 50 Hz to 10 kHz). Once all voltage transformers located in the vicinity of the voltage measurement point and covered by the power grid have been calibrated, the (at least a second) voltage transformer with a known transfer function (e.g. a capacitive voltage transformer or, for example, a correspondingly measured inductive voltage transformer) can be replaced again by the voltage transformer previously comprised by the power grid. Based on the calibration factor determined for the other inductive voltage transformers, for example, a corresponding calibration factor can then be determined for the replaced voltage transformer.

According to an exemplary embodiment of all aspects of the invention, the correction factor is determined for a frequency range from 50 Hz to 2.5 kHz, in particular from 50 Hz to 5 kHz, particularly preferably from 50 Hz to 10 kHz, by means of the at least one second voltage transformer.

In this way, the at least one first voltage converter can be calibrated, for example, for an extended frequency range, presently from 50 Hz to 10 kHz. This extended frequency range is particularly useful for determining (e.g. deriving) possible harmonics that may occur in the power grid, e.g. due to the feeding of electrical energy through one or more WTGs.

According to an exemplary embodiment of all aspects of the invention, the correction factor is determined for all electrically close inductive voltage transformers.

The term “electrically close” is understood in particular that the corresponding electrically close component is comprised by the power grid, and in particular is arranged, for example, on an identical busbar as the at least one second voltage transformer or is connected by a cable to the at least one second voltage transformer directly, i.e. without diversion via remote structures of the power grid.

In addition, corresponding correction factors and subsequently corresponding calibration factors can be determined for all electrically close inductive voltage transformers. Furthermore, for all electrically close inductive voltage transformers as at least one first voltage transformer, the respective determined calibration factor can be output or its respective output can be initiated.

Accordingly, the method can be carried out and/or controlled, for example, for a plurality of first voltage transformers, in particular by means of the at least one second voltage transformer, which is arranged electrically close to the plurality of first voltage transformers in the power grid (e.g. on the identical busbar).

According to an exemplary embodiment of all aspects of the invention, the electrically close at least one first voltage transformer is calibrated for an extended frequency range (e.g. from 50 Hz to 10 kHz) at least partially based on the respective determined calibration factor.

In particular, for example, several electrical close first voltage transformers for the extended frequency range can be calibrated at least partially based on the respective calibration factor determined from the several first voltage transformers.

According to an exemplary embodiment of all aspects of the invention, the at least one second voltage transformer is a capacitive or a measured inductive voltage transformer.

A measured inductive voltage transformer is understood to be, in particular, an inductive voltage transformer that was measured before an arrangement of it in the power grid so that its transfer function was determined and/or is already known before it is arranged in the power grid. Based on the determined and/or known transfer function of the measured inductive voltage transformer (in this case the at least one second voltage transformer), the transfer function of the at least one first voltage transformer can be determined accordingly.

A capacitive voltage transformer is understood to be a voltage transformer that has a high insulation strength at high voltages. In contrast to this, this can only be ensured with great effort in the transformer or high costs in the case of inductive voltage transformers. Such a capacitive voltage transformer has a (high voltage resistant) capacitor which is connected to a voltage to be measured (e.g. by means of a busbar). Such capacitive voltage transformers determine in particular correct measured values even in the extended frequency range of 50 Hz to 10 kHz, since they are essentially insensitive to occurring impairments of the power grid (e.g. harmonics, or resonances, to name only a few non-limiting examples).

According to an exemplary embodiment of all aspects of the invention, the corrected transfer function for the at least one first voltage transformer is re-adjusted at least partially based on the correction factor.

The transfer function for the at least one first voltage transformer can be re-adjusted by software, for example. For example, by determining the change (e.g. of electrically close) further first voltage transformers and applying it to the transfer function of the at least one first voltage transformer, its transfer function can be readjusted. Alternatively or additionally, the transfer function of the at least one first voltage transformer can be re-adjusted in case the at least one first voltage transformer has an interface (e.g. a digital input or the like). The at least one first voltage transformer can be controlled and/or regulated via the interface, for example. Furthermore, the interface could be of analogue design. In this case the transfer function of the at least one first voltage converter can be re-adjusted, for example, by using a current (e.g. from 0 to 20 mA) to transmit a correspondingly modulated control signal for re-adjusting the transfer function of the at least one first voltage converter.

According to an exemplary embodiment of all aspects of the invention, the determined correction factor and/or the corrected transfer function are stored in a memory.

The memory comprises a database, for example. In the database, for example, a link between an identification information (e.g. ID of at least one first voltage transformer) and a correction factor, a calibration factor, a transfer function, or a combination of these can be stored. Based on the identification information, a network control system can, for example, query the correction factor, the calibration factor, the transfer function or a combination thereof and use it for further applications, e.g. for correcting measured values determined by the at least one first voltage transformer.

In addition, the memory, in particular the database comprised by the memory, can store (e.g. store) the specific correction factor and/or the corrected transfer function as a function of the switching state of the power grid and/or the operating state of the one or more components of the power grid in which and/or in which at least the specific correction factor and/or the corrected transfer function was determined.

The memory or the database comprised by the memory can alternatively or additionally be integrated in a grid unit (e.g. from a voltage measuring point, wherein the grid unit transmits the measured values determined e.g. to a network control system) for the correction of measured values determined by the at least one first voltage transformer, comprised by it or connected to it. Correspondingly, a correction of the measured values determined by the at least one first voltage transformer can take place directly in the grid unit. Accordingly, the grid unit transmits, for example, already corrected measured values, e.g. to a network control system, so that this network control system does not have to carry out any further correction of the measured values of the at least one first voltage transformer at least partially based on the correction factor, the calibration factor, the transfer function or a combination thereof.

In the event that several first voltage transformers are comprised by the power grid, at least one correction factor and/or a corrected transfer function may be stored in the memory, in particular in the database comprised by the memory, for each of the first voltage transformers comprised by the power grid.

The forms of execution and exemplary embodiments of all aspects of the present invention, which are described above and which are initially basically stand alone, should also be understood in all combinations with each other in a disclosed manner.

Further advantageous exemplary embodiments of the invention can be found in the following detailed description of some exemplary embodiments of the present invention, especially in connection with the figures. However, the figures enclosed with the application should only serve the purpose of clarification, but not to determine the scope of protection of the invention. The enclosed drawings are not necessarily to scale and are merely intended to illustrate the general concept of the present invention. In particular, features contained in the figures should not necessarily be considered as a necessary element of the invention.

### BRIEF DESCRIPTION OF THE DRAWINGS

In the drawing shows

FIG. 1 an exemplary system according to an example embodiment;

FIG. 2 a flow chart of an exemplary method based on an example embodiment;

FIG. 3 a schematic illustration of an example embodiment of an apparatus which can, for example, execute and/or perform the method according to all exemplary aspects; and

FIG. 4 different example embodiments of a storage medium.

### DESCRIPTION OF THE INVENTION

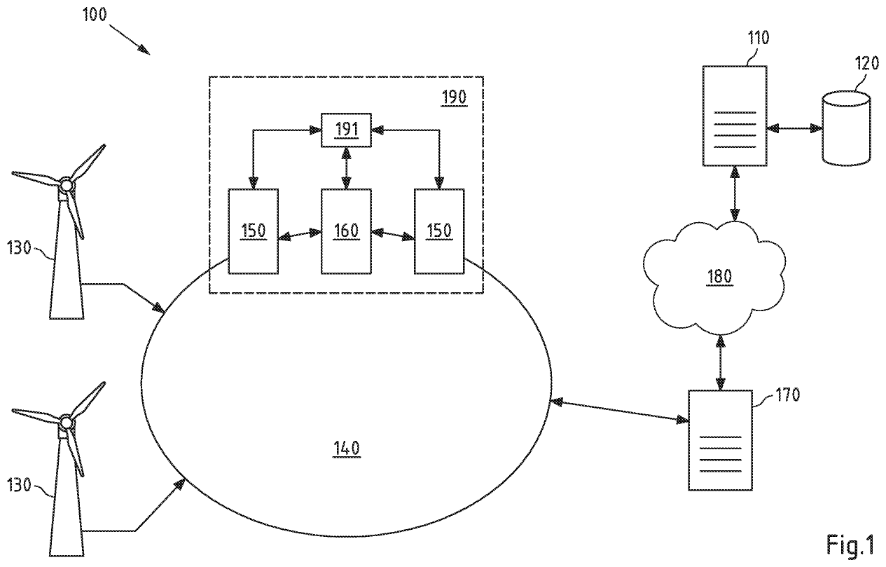

FIG. 1 shows an exemplary system 100 of an example embodiment according to the fourth aspect of the present invention. The system 100 comprises in the present case two of first voltage transformers 150, a second voltage transformer 160, a grid unit 191 comprised by a voltage measuring point 190, a server 170 which, for example, executes and/or controls a network control system and/or executes and/or controls a simulation software, a server 110 which, for example, performs and/or controls the present method according to the first aspect of the present invention, an optional database 120, in the present case two WTGs 130 which feed electrical energy into the power grid 140, and a communication network 180 (e.g. the Internet), via which at least server 170 can communicate with server 110. Alternatively, server 170 and server 110 can be directly connected to each other and communicate, for example, via a wired communication connection (e.g. according to the Local Area Network (LAN) standard). Alternatively, the server 110 can be comprised by the server 170 so that a concrete (i.e. tangible) server executes and/or controls e.g. both a network control system of the power grid 140 and the method according to the first aspect of the invention.

In example embodiments of the present invention, for example, a correction factor is determined, e.g. by the server 110, by first determining a first voltage from one or both of the first voltage transformers 150. Then, for example, the second voltage transformer 160 is temporarily installed in the power grid, e.g. on the same busbar as the other two first voltage transformers 150. Alternatively, the second voltage transformer 160 can replace one of the first two voltage transformers 150 (not shown schematically in FIG. 1).

The first voltage of the at least one first voltage transformer 150 and a second voltage of the at least one first voltage transformer 150 is determined, for example, by determining the first (frequency-dependent) voltage, e.g. before the second voltage transformer 160 is placed in the power grid 140. The second (frequency-dependent) voltage is determined after the second voltage transformer 160 has been placed in and comprised by the power grid 140. The second voltage of the at least one first voltage transformer 150 is determined at least partially based on a previously known transfer function of the at least one second voltage transformer 160, e.g. corresponds to the correct voltage measured at the at least one first voltage transformer 150.

After the first and second voltages have been determined, they are transmitted, for example, from the grid unit 191 to the server 110, e.g. via the server 170 connected to the power grid 140 and the communication network 180 (e.g. the Internet). Accordingly, at least the grid unit 191 can establish a communication connection via the communication network 180 to the server 110 and use it for transmitting, for example, the first and second voltage from at least one of the first two voltage transformers 150. The server 110 then determines a correction factor of the at least one first voltage transformer 150 at least partially based on the first and the second determined voltage.

At least partly based on the determined correction factor, the server 110, for example, determines a calibration factor. This calibration factor for the at least one first voltage transformer 150 can be determined, for example, by making the correct voltage correspond to the voltage determined from the first voltage, the correct voltage and the second voltage, for example according to the following formula:

Calibration factor for the at least one first voltage transformer 150=first voltage*(correct voltage/second voltage),

where the respective voltages can be determined e in each case depending on the frequency.

The determined calibration factor is then output, e.g. from the server 110 to the server of the network control system 170, which can use the calibration factor to determine the correct voltage at at least one of the first voltage transformers 150. Based on the correct voltage, the server of the network control system 170 can, for example, quickly and reliably measure any harmonics that may occur or have already occurred in the power grid 140, so that, for example, suitable measures can be taken in good time to eliminate or avoid harmonics in the power grid 140, e.g. by a non-uniform feed of electrical energy into the power grid 140 by the WTG 130.

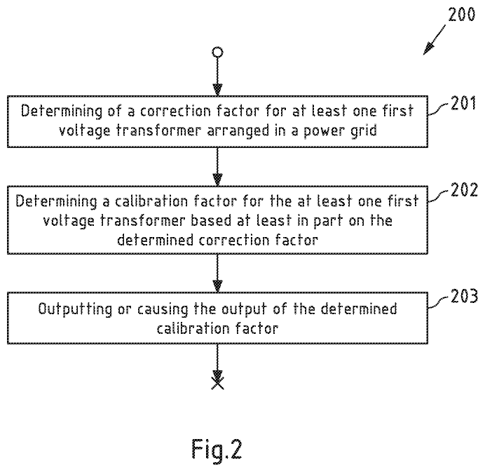

FIG. 2 shows a flowchart 200 of an example method according to an example embodiment in accordance with the first aspect of the invention. The flowchart 200 can be performed and/or controlled by the server 110 according to FIG. 1. Alternatively or additionally, the flowchart 200 can be performed and/or controlled by the grid unit 191 according to FIG. 1.

In a first step 201, a correction factor is determined for at least one first voltage transformer (e.g. one of the voltage transformers 150 according to FIG. 1) arranged in a power grid (e.g. power grid 140 according to FIG. 1).

The correction factor is indicative of a correction for obtaining correct measured values measured by the at least one first voltage transformer (e.g. one of the voltage transformers 150 according to FIG. 1), wherein the determining of the correction factor of the at least one first voltage transformer is based at least partially on a first voltage of the at least one first voltage transformer and a second voltage of the at least one first voltage transformer, wherein the second voltage of the at least one first voltage transformer is determined at least partially based on a known transfer function of at least one second voltage transformer (e.g. voltage transformer 160 according to FIG. 1) and the first voltage of the at least one first voltage transformer is determined, wherein the correction factor of the at least one first voltage transformer is determined without taking into account the previously known transfer function of the at least one second voltage transformer.

In a second step 202, a calibration factor for the at least one first voltage transformer (e.g. voltage transformer 150 according to FIG. 1) is determined at least partially based on the determined correction factor.

In a third step 203 an output or initiation of the output of the determined calibration factor is performed, e.g. from the server 110 according to FIG. 1 to the server of the network control system 170 according to FIG. 1.

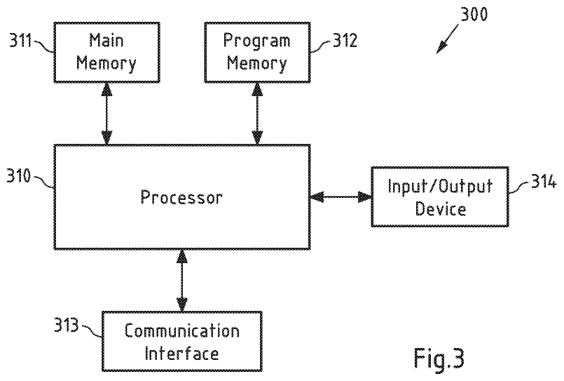

FIG. 3 shows a schematic representation of an example embodiment of an apparatus 300, which can be used in the context of all exemplary aspects. The apparatus 300 represents, for example, the server 110 according to FIG. 1, or the server of the network control system 170 according to FIG. 1, or the grid unit 191 according to FIG. 1, which is comprised by the voltage measuring point of the power grid (power grid 140 according to FIG. 1).

The apparatus 300 can, for example, execute and/or control the method according to all aspects. For this purpose, the apparatus can, for example, have and/or comprise means for executing and/or controlling the method according to all aspects. Furthermore, the present method according to all aspects can be executed and/or performed by several (i.e. at least two) apparatuses 300.

The apparatus 300 can, for example, execute the flow chart 200 of FIG. 2.

The apparatus 300 comprises a processor 310 with assigned main memory 311 and program memory 312, for example, the processor 310 executes program instructions stored in program memory 312. The program instructions execute and/or control the method (e.g. according to steps 201 to 203 of FIG. 2). Thus, program memory 312 comprises a computer program and represents a computer program product for its storage. Apparatus 300 represents an example of an apparatus of a system (e.g. the system 100 according to FIG. 1).

For example, program memory 312 can be a persistent memory such as read-only memory (ROM). For example, Program Memory 312 can be permanently connected to the processor 310, but alternatively it can also be detachably connected to the processor 310, for example as a memory card, floppy disk, or optical data storage medium (such as a CD or DVD). Additional information can also be stored in program memory 312, or in a separate memory.

Main memory 311 is used, for example, to store temporary results during the execution of program instructions. This is volatile memory, such as random access memory (RAM).

The processor 310 is also operatively connected to a communication interface 313, which allows, for example, information exchange with other devices (see e.g. the arrows in FIG. 1). By means of the communication interface 313, for example, a certain calibration information can be output (step 203 of FIG. 2).

The apparatus 300 can comprise further components. If the apparatus 300 represents the apparatus for executing and/or performing an objective method (e.g. server 110 according to FIG. 1), an optional determining unit (not shown in FIG. 3) is provided, which is set up, for example, to determine a correction factor (step 201 according to FIG. 2) and is operatively connected to the processor 310. Furthermore, a determining unit (not shown in FIG. 3) is optionally provided, which is set up, for example, to determine a calibration factor (step 202 according to FIG. 2) and is operatively connected to the processor 310.

Optionally, the apparatus 300 may have a user interface (e.g. an input/output device 314) which allows, for example, the displaying of information (e.g. optical reproduction). For example, the user interface is a display device (e.g. a liquid crystal display (LCD), or a light emitting diode (LED) display or similar). In addition, the user interface can be used to record one or more user inputs, e.g. a keyboard, mouse, or touch-sensitive display device.

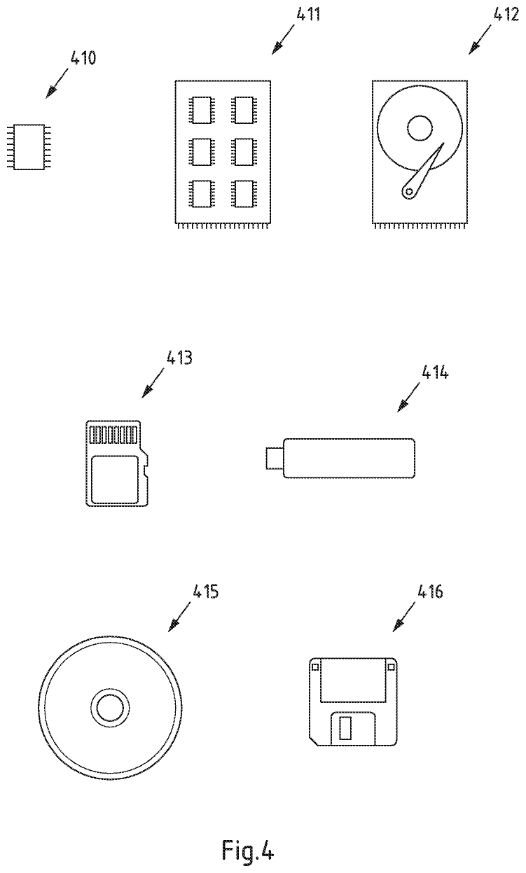

FIG. 4 shows different examples of storage media on which an example embodiment of a computer program according to the invention can be stored. The storage medium can be, for example, a magnetic, electrical, optical and/or other type of storage medium. The storage medium may, for example, be part of a processor (e.g. processor 310 of FIG. 3), for example (a non-volatile or volatile) program memory of the processor or a part thereof (such as program memory 312 of FIG. 3). Example embodiments of a storage medium are a flash memory 410, an SSD hard disk 411, a magnetic hard disk 412, a memory card 413, a memory stick 414 (e.g. a USB stick), a CD-ROM or DVD 415, or a floppy disk 416.

The example embodiments of the present invention described in this specification and the optional features and properties mentioned in each case should also be understood as disclosed in all combinations. In particular, unless explicitly stated otherwise, the description of a feature included in an example embodiment shall not be understood in the present case to mean that the feature is indispensable or essential for the function of the example. The sequence of the method steps described in this specification in the individual flowcharts is not mandatory; alternative sequences of method steps are conceivable. The method steps can be implemented in various ways, for example, implementation in software (through program instructions), hardware or a combination of both to implement the method steps is conceivable.

Terms used in the claims such as “comprise”, “have”, “include”, “contain” and the like do not exclude further elements or steps. The expression “at least partially” covers both the “partially” case and the “completely” case. The wording “and/or” should be understood to mean that both the alternative and the combination should be disclosed, i.e. “A and/or B” means “(A) or (B) or (A and B)”. The use of the indefinite subject-matter does not exclude a plural. A single apparatus may perform the functions of several units or apparatuses mentioned in the claims. Reference signs indicated in the claims are not to be regarded as limitations of the means and steps used.

1. A method performed by at least one apparatus, comprising:
determining of a correction factor for at least one first voltage transformer arranged in a power grid, the correction factor being indicative of a correction for obtaining correct measured values measured by the at least one first voltage transformer, wherein the determining of the correction factor of the at least one first voltage transformer being performed at least partially based on a first measured voltage of the at least one first voltage transformer and a second measured voltage of the at least one first voltage transformer, wherein the second measured voltage of the at least one first voltage transformer is determined at least partially based on a known transfer function of at least one second voltage transformer and the first measured voltage of the at least one first voltage transformer is determined without taking into account the known transfer function of the at least one second voltage transformer,
thereby the second measurement of the first transformer is multiplied by the quotient from the frequency-dependent measurements of the second transformer divided by the previously recorded frequency-dependent first measurements of the first transformer, this quotient being referred to as the transfer function, and the correction factor for a frequency range from 50 Hz to 10 kHz being determined by means of the at least one second voltage transformer;
determining a calibration factor for the at least one first voltage transformer based at least in part on the determined correction factor; and
outputting or causing the output of the determined calibration factor.

2. The method according to claim 1, further comprising:
determining a corrected transfer function for the at least one first voltage transformer, wherein the corrected transfer function is determined at least in part based on the determined calibration factor; and
outputting or causing the output of the corrected transfer function.

3. The method according to claim 1, wherein the at least one second voltage transformer is temporarily comprised by the power grid.

4. The method according to claim 1, wherein the determining of the first voltage and/or the second voltage of the at least one first voltage transformer is carried out at all three phases of a voltage measuring point existing in the power grid.

5. The method according to claim 1, wherein for all occurring switching states of the power grid and/or operating states of one or more components of the power grid the steps of the method according to one of the claims 1 to 4 are carried out.

6. The method according to claim 3, wherein the at least one second voltage transformer is temporarily arranged in or comprised by the power grid for a measuring period of approximately one day to 6 months.

7. (canceled)

8. The method according to claim 1, wherein the determining of the correction factor is performed for all electrically close inductive voltage transformers.

9. The method according to claim 1, wherein the electrically near at least one first voltage transformer is calibrated for an extended frequency range at least partially based on the respective determined calibration factor, wherein the electrically near at least one first voltage transformer is comprised by the power grid and is at an identical busbar as the at least one second voltage transformer or via a cable directly connected with the at least one second voltage transformer.

10. The method according to claim 1, wherein the at least one second voltage transformer is a capacitive or a measured inductive voltage transformer.

11. The method according to claim 2, wherein the corrected transfer function for the at least one first voltage transformer is re-adjusted at least partially based on the correction factor.

12. The method according to claim 2, wherein the determined correction factor and/or the corrected transfer function are stored in a memory.

13. An apparatus arranged to execute and/or control the method according to claim 1 or comprising respective means for executing and/or controlling the steps of the method.

14. A system comprising one or more apparatuses arranged to execute and/or control the method according to claim 1 or having means to execute and/or control the steps of the method.

15. A computer program comprising program instructions which cause a processor to execute and/or control the method according to claim 1 when the computer program is executed by the processor.
